(19) United States
(12) Patent Application Publication
(10) Pub. No.: US 2010/0201387 A1
(43) Pub. Date: Aug. 12, 2010

(54) Safety-Enhanced Component and Circuit Tester

(76) Inventor: Michael Jakeman, Norwood, CO (US)

Correspondence Address: Michael F. Krieger;Kirton & McConkie, 60 East South Temple, Suite 1800, Salt Lake City, UT, 84111, US

(21) Appl. No.: 12/702,051

(22) Filed: Feb. 8, 2010

Related U.S. Application Data
(60) Provisional application No. 61/151,771, filed on Feb. 11, 2009.

(51) Int. Cl. G01R 1/067; G01R 31/02

(52) U.S. Cl. 324/754

(57) ABSTRACT

Circuit testers used with digital logic and its associated components are described. The circuit testers better protect the user, better protect the equipment, and provide testers in a form that is easy and safe to use. The tester includes a body member with a hand guard or hand protector and that includes a trigger switch, a fuse housing, a probe, and a second lead connector. All components are rated for at least the maximum voltage and current expected for the device. The hand guard serves as a physical barrier to any exposed voltages. The trigger switch provides for secure placement of the test lead and probe before energizing the circuit or component. To protect the equipment being tested, the maximum desired current to the test location can be identified and a properly-sized fuse installed in the fuse housing, protecting the existing equipment being tested from further damage by excessive currents.

### CROSS-REFERENCE TO RELATED APPLICATIONS

This application claims the benefit of U.S. Provisional Application No. 61/151,771 filed Feb. 11, 2009.

### BACKGROUND OF THE INVENTION

1. Field of the Invention

The present invention relates to testing and troubleshooting of digital logic circuits and more particularly to devices and methods that provide improved safety and protection of users and of circuit components during testing and troubleshooting.

2. Background and Related Art

Many testers have been previously provided for testing electrical circuits; some test voltage, others current, continuity and/or other electrical conditions. However, for those skilled in the art of electrical control systems there has been a need to simply jump a device out. The most common method is to use an “alligator jumper” to simply bypass a device or to jump source power to the device. Older electrical motor controls books encourage the student to include a fuse in the center of the jumper for protection purposes; however, the most common method used by those skilled in the art is to use a spare piece of wire stripped at both ends to apply source power to the device being tested at the desired location for test purposes.

Such methods are limited in several regards. Un-fused wires fail to provide protection for the equipment, as large voltages and currents may be provided to incorrect locations. Such undesired voltages and currents may damage equipment or components not previously broken, worsening the equipment being tested.

Additionally, both a fused wire and an un-fused wire fail to provide any protection to the person using the wire. As power is supplied to the equipment being tested, arcs commonly occur between the equipment and the wire ends. Such arcs can damage equipment, startle the user, and may lead to incorrect wire placement or electrical shocks to the user. For example, a user who has experienced a startling arc in the past may be prone to wincing, closing his or her eyes during placement of the wire end, and the like. Such activities commonly result in incorrect wire end placement or inadvertent touching of a live portion of a circuit by the user's hand or other body part. As may be appreciated, equipment damage or user injury may thus result.

Recently Personal Protection has become more of an issue when troubleshooting electrical controls systems. New codes have been implemented or suggested by the National Fire Protection Agency (NFPA) such as NFPA 70E. Such codes limit unprotected access to electrical components and circuitry. Such codes are relevant, for example, when testing the coil (or the engaging portion) of a motor starter with exposed three-phase 480 VAC contacts. The terminals for the coil or the engaging portion are typically located above the exposed 480 VAC contacts. In this example, NFPA 70E is designed to limit unprotected inadvertent contact between a body part and the exposed 480 VAC contacts while accessing the coil or the engaging portion. Nevertheless, existing equipment fails to provide the desired protection.

### BRIEF SUMMARY OF THE INVENTION

Implementation of the invention relates to a circuit tester used with digital logic and its associated components, more particularly to circuit testers used with motor controls, relay logic, programmable logic controllers (PLCs), digital control systems (DCSs), and the like. Implementations of the invention protect the user, protect the equipment, and provide a tester in a form that is easy and safe to use.

Implementation of the invention thus provides a body member that includes a hand guard or hand protector and that includes a trigger switch, a fuse housing, a probe, and a second lead connector. All components are rated for at least the maximum voltage and current expected for the device, such as, for example, 10 amps at 250 VAC. The hand guard or hand protector serves as a physical barrier between the individual and any exposed voltages, and therefore, the body and hand guard are manufactured from a material providing electrical insulation of at least the maximum expected voltage and current (e.g. 10 amps at 250 VAC). Such materials include rubber and plastic.

The trigger switch provides for secure placement of the test lead and probe before energizing the circuit or component by completing the jumped connection, thereby preventing most mistakes; most mistakes are made while trying to get secure placement of the probes while an electrical arc is occurring.

The fuse housing is rated for fuses up to at least the maximum expected voltage and current (e.g. 10 amp fuse at 250 VAC); however, to protect the equipment being tested, the maximum desired current to the test location can be identified and a properly-sized fuse installed in the fuse housing. Thus, the existing equipment being tested is protected from further damage by excessive currents.

### BRIEF DESCRIPTION OF THE SEVERAL VIEWS OF THE DRAWINGS

The objects and features of the present invention will become more fully apparent from the following description and appended claims, taken in conjunction with the accompanying drawings. Understanding that these drawings depict only typical embodiments of the invention and are, therefore, not to be considered limiting of its scope, the invention will be described and explained with additional specificity and detail through the use of the accompanying drawings in which:

FIG. 1 shows a plan view of a representative component and circuit tester in accordance with embodiments of the present invention;

FIG. 2 shows a plan electrical circuit diagram of a representative component and circuit tester; and

FIG. 3 shows a flow chart for a method in accordance with embodiments of the present invention.

### DETAILED DESCRIPTION OF THE INVENTION

A description of embodiments of the present invention will now be given with reference to the Figures. It is expected that the present invention may take many other forms and shapes, hence the following disclosure is intended to be illustrative and not limiting, and the scope of the invention should be determined by reference to the appended claims.

Embodiments of the invention relate to a circuit tester used with digital logic and its associated components, more particularly to circuit testers used with motor controls, relay logic, programmable logic controllers (PLCs), digital control systems (DCSs), and the like. Embodiments of the invention first, protect the user, second, protect the equipment, and third, provide a tester in a form that is easy and safe to use.

Embodiments of the invention thus provide a body member that includes a hand guard or hand protector and that includes a trigger switch, a fuse housing, a probe, and a second lead connector. All components are rated for at least the maximum voltage and current expected for the device, such as, for example, 10 amps at 250 VAC. The hand guard or hand protector serves as a physical barrier between the individual and any exposed voltages, and therefore, the body and hand guard are manufactured from a material providing electrical insulation of at least the maximum expected voltage and current (e.g. 10 amps at 250 VAC). Such materials include rubber and plastic.

The trigger switch provides for secure placement of the test lead and probe before energizing the circuit or component by completing the jumped connection, thereby preventing most mistakes; most mistakes are made while trying to get secure placement of the probes while an electrical arc is occurring.

The fuse housing is rated for fuses up to at least the maximum expected voltage and current (e.g. 10 amp fuse at 250 VAC); however, to protect the equipment being tested, the maximum desired current to the test location can be identified and a properly-sized fuse installed in the fuse housing. Thus, the existing equipment being tested is protected from further damage by excessive currents.

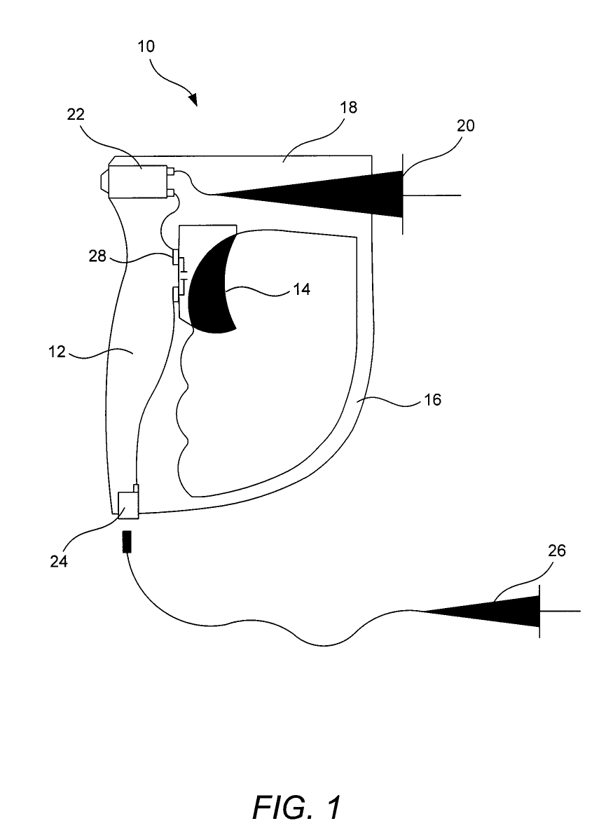

FIG. 1 provides a plan view of a representative embodiment of a component or circuit tester (“tester 10”). The illustrated tester 10 is representative of the features that may be included in embodiments of the invention. The tester 10 includes a hand grip 12, which may be ergonomically formed for easy and secure gripping, as well as for comfortable use of the tester 10. Inset into the hand grip 12 is a trigger 14 that permits a user to trigger operation of the tester 10. The tester 10 also includes a hand guard 16 that serves to protect the operator's hand from inadvertent and undesired contact with any live electrical components of the device or equipment being tested. The tester 10 has an upper body portion 18 connecting upper ends of the hand grip 12 and the hand guard 16. The upper body portion 18, the hand guard 16, and the hand grip 12 are manufactured from a material capable of providing electrical isolation from internal components and external devices with respect to the user, up to a desired minimum protection level, such as at least ten amps at 250 VAC. Examples of suitable materials for such electrical isolation include various kinds of plastic and natural and synthetic rubber materials.

The upper body portion 18, the hand guard 16, and the hand grip 12 for a body of the tester 10. The body provides a convenient location to grip the tester 10 while maneuvering any probe of the tester 10 to a desired location and simultaneously preventing inadvertent contact with undesired electrical components. The body also houses additional components of the tester 10, including a test probe 20, a fuse housing 22, and a lead connector 24. The test probe 20 may be integrally formed as part of the body, or it may be removable or interchangeable, depending on the uses to which the tester 10 will be put. The fuse housing 22 houses a replaceable and interchangeable fuse. The lead connector 24 provides a connection to a test lead 26, and may provide any standard or non-standard connection. One example of a standard connection is a banana-style plug terminal.

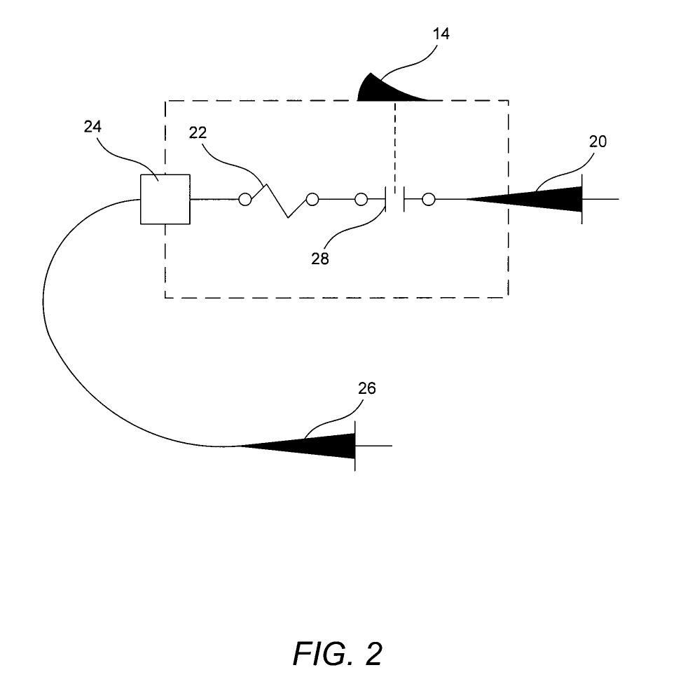

The lead connector 24, the fuse housing 22, and the test probe 20 are electrically connected in series with a normally-open switch 28 controlled by the trigger 14, as is illustrated in FIG. 2. While one particular series order is illustrated, other orders (e.g. switching the order of the series connections to the fuse housing 22 and the trigger 14/switch 28) are contemplated as being equally serviceable. When the trigger 14 is not depressed, the switch 28 is open, and no current can flow between the lead connector 24 (or any connected test lead 26) and the test probe 20. When the trigger is depressed, the switch 28 is closed, and current can flow between the lead connector 24 (or any connected test lead 26) and the test probe 20 if any difference in potential exists between the lead connector 24 and the test probe 20. All electrical devices (e.g. the test probe 20, the fuse housing 22, the switch 28, the lead connector 24, and the test lead 26) and the internal or external connections between them are rated to at least the minimum desired test level (e.g. ten amps at 250 VAC).

Although the hand guard 16 is illustrated in FIG. 1 as being a relatively small piece extending forward of the user's hand when gripping the hand grip 12, the hand guard 16 may take other configurations for functional or aesthetic reasons. One potential reason why the hand guard 16 may be kept narrow is to reduce a profile of the tester 10, so the tester 10 lies relatively flat on its side, such as for storage. One reason why the hand guard 16 may be extended further to the left and right is to further improve protection for the user's hand while holding the tester 10. Thus, the hand guard 16 may be extended in either direction to any desired degree, including to a point where it essentially envelopes the user's hand on all sides forward of the hand grip 12. As may be appreciated, in such embodiments it will be more difficult for the user to inadvertently contact an exposed portion of the user's hand to a live portion of the tested circuit or device.

The normally-open switch 28 activated or closed by the trigger 14 provides distinct advantages to the tester 10, in that it prevents any arcing of the circuit or device to be tested as the tester 10 is contacted to the respective power terminals and test points of the tested device. Using old techniques, it was common for an arc to occur as the stripped wire end was brought into proximity with the location to be tested or to the power terminal. The arcing that occurred using such methods can be startling and may lead to equipment damage or improper placement of the stripped wire lead. The switch 28 and trigger 14 of the tester 10 makes it possible to eliminate many of these problems by allowing proper and secure placement of the test lead 26 and the test probe 20 while the circuit is open. Thus, no arcing occurs while the leads are placed.

When the user has properly placed the test lead 26 and the test probe 20, the user can then pull the trigger 14, closing the switch 28 and completing the circuit. Any arcing that occurs is located within the switch 28 and is therefore hidden from the user by the body of the tester 10, thereby eliminating or greatly reducing the likelihood of the user being startled by the arc. The user can similarly release the trigger 14 upon completion of any test, thereby opening the switch 28 and disconnecting the circuit, prior to removing the test lead 26 and/or the test probe 20, thereby preventing any arcing from occurring as the test lead 26 and the test probe 20 are removed.

To further minimize the possibility of equipment damage, the current rating for the device to be tested can be determined and a properly-sized fuse located in the fuse housing 22 of the tester 10 prior to any test occurring. Thereafter, any testing of the device that occurs using the tester 10 is ensured to be limited to the maximum current-handling capability of the device being tested, and no additional equipment damage is therefore caused by the testing. Instead, before damage occurs, the relatively-inexpensive fuse in the fuse housing 22 blows as the current through the tester 10 exceeds the current rating of the selected fuse prior to exceeding the current rating of the equipment being tested.

Embodiments of the tester 10 can be used in a variety of applications. Examples of use of the device include situations where an input/output device or system component is in question as to whether it is properly functioning. Devices that can be tested include PLCs, DCSs, relays, motor starters, switches, wires, fuse blocks, terminal blocks, lights, or any input/output device or system component that uses digital logic (e.g. on/off). Power to test the component/device is external to the tester 10 (and is generally contacted by the test lead 26) and can be of any desirable DC or AC voltage, such as those ranging from 12-200 VAC or VDC.

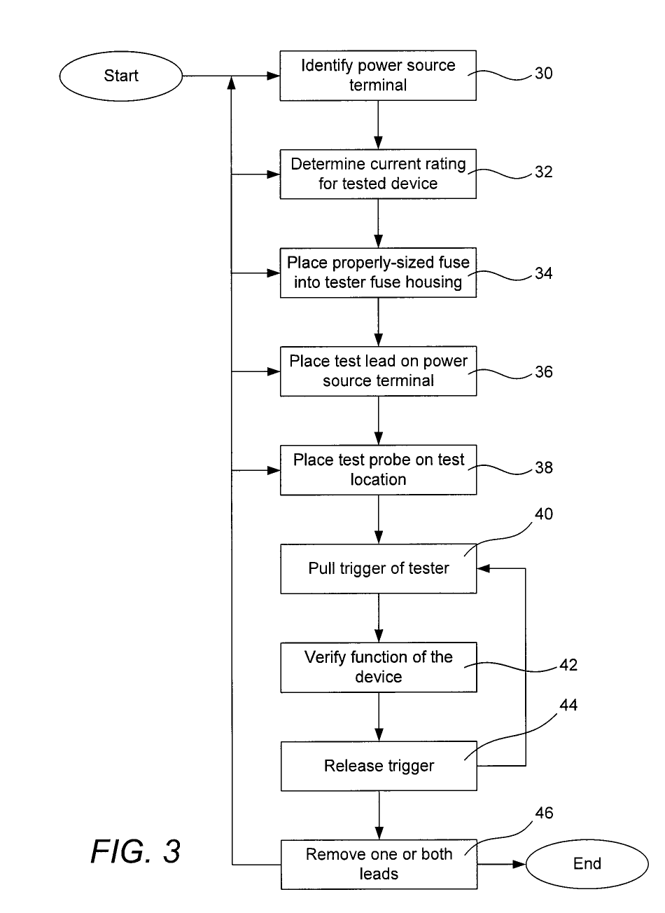

FIG. 3 provides a flow chart illustrating use of embodiments of the tester 10. Execution presumes a tester 10 is available and that a state of a device or component to be tested is in question. Execution begins with step 30, where the user identifies a proper power source terminal for the device. In at least some instance, the power source terminal can be external to the device, and it is envisioned that in at least some instances, the proper source terminal can be a ground terminal. Once the power source terminal is identified, a current rating for the device (or component thereof) to be tested is identified at step 32. Then, at step 34, a properly-sized fuse (to limit any potential currents supplied to the device through the tester 10) is placed in the fuse housing of the tester 10, and the tester 10 is ready for use to test the device or component.

Once the tester 10 is ready for use, the test lead 26 is placed on the power source terminal at step 36, and the test probe 20 is placed touching the input/output device or system component input terminal being tested at step 38. (It will be appreciated that the order of steps 36 and 38 may be reversed.) Once both leads are properly placed, the user pulls the trigger 14 at step 40, thus completing the circuit between the power source terminal and the test location, whereupon functioning of the device is verified at step 42 and the trigger 14 is thereafter released at step 44. If the user desires to repeat the test at the same location, execution returns to step 40, where the trigger is pulled again. If testing at a location is finished, execution proceeds to step 46, where one or both of the test lead 26 and the test probe 20 are removed from their respective test locations.

If further testing is desired, execution can then loop back to any of steps 30 through 38 for testing to continue. However, if testing is completed, execution ends after both leads are removed. The tester 10 can then be stored until it is needed again. Although not specifically shown in FIG. 3, if the fuse in the fuse housing 22 has blown as a result of the testing, it is discarded and/or replaced before further testing occurs. In some instances, one or more steps illustrated in the flow chart of FIG. 3 may be skipped. For example, if, after step 32, a current rating is determined that matches a fuse already in the fuse housing 22, step 34 may be skipped.

Thus it may be seen that embodiments of the invention provide systems and methods for improved jump-out testing of various types of electrical systems, devices, and components. The embodiments of the invention improve safety and protection of the user while providing improved equipment protection and a simple, easy-to-use device.

The present invention may be embodied in other specific forms without departing from its spirit or essential characteristics. The described embodiments are to be considered in all respects only as illustrative and not restrictive. The scope of the invention is, therefore, indicated by the appended claims, rather than by the foregoing description. All changes which come within the meaning and range of equivalency of the claims are to be embraced within their scope.

What is claimed and desired to be secured by Letters Patent is:

1. A safety test jumper comprising:
a body comprising:
a hand grip having an upper end and a lower end;
an upper body portion housing a probe, the upper body portion having a rear portion attached at the upper end of the hand grip and a front portion; and
a hand guard extending between the lower end of the hand grip and the front portion of the upper body portion;
the probe comprising an electrical contacting portion at the front portion of the upper body portion;
a fuse housing incorporated into the body and configured to receive a fuse;
a trigger incorporated into the body at a location that it can be readily activated by a user's hand gripping the hand grip;
a switch within the body activated by the trigger; and
a lead connector incorporated into the body and configured to receive a test lead;
wherein the probe, the fuse housing, the switch, and the lead connector are electrically connected in series, whereby an electrically-contiguous connection between the probe and the lead connector is only made when a fuse is in the fuse housing and the trigger is depressed.

2. A safety test jumper as recited in claim 1, further comprising a test lead connected to the lead connector.

3. A safety test jumper as recited in claim 1, further comprising a fuse connected to the fuse housing.

4. A safety test jumper as recited in claim 3, wherein the fuse is sized to prevent currents higher than a rated current of the device being tested from being delivered to the device being tested.

5. A safety test jumper as recited in claim 1, wherein the safety test jumper has a pistol configuration with the upper body portion and probe forming a barrel of the pistol configuration.

6. A safety test jumper as recited in claim 1, wherein the hand grip is ergonomically formed.

7. A safety test jumper as recited in claim 1, wherein the body is formed of an electrically-insulating material.

8. A safety test jumper as recited in claim 7, wherein the electrically-insulating material comprises a material selected from the group consisting of:
natural rubber;
synthetic rubber; and
plastic.

9. A safety test jumper as recited in claim 1, wherein the switch is a normally-open switch that is configured to be switched to a closed state by depression of the trigger and is further configured to automatically return to the normally-open switch upon release of the trigger.

10. A safety test jumper as recited in claim 1, wherein the hand guard extends laterally to substantially cover the user's hand when the user's hand is gripping the hand grip.

11. A component and circuit tester comprising:
a body comprising:
an insulating hand grip having an upper end and a lower end;
an upper body portion housing a probe, the upper body portion having a rear portion attached at the upper end of the hand grip and a front portion where at least portion of the probe is exposed, wherein the hand grip and the upper body portion form a pistol-type configuration; and
a hand guard extending in front of the hand grip between the lower end of the hand grip and the front portion of the upper body portion, thereby defining a space encompassed by the hand grip, the upper body portion, and the hand guard;
the probe comprising an electrical contacting portion at the front portion of the upper body portion;
a fuse housing incorporated into the body and configured to receive a fuse;
a trigger incorporated into the body at a location that it can be readily activated by a user's hand when the user's hand is gripping the hand grip;
a normally-open switch within the body mechanically activated by the trigger to a temporary switched closed state; and
a lead connector incorporated into the body and configured to receive a test lead;
wherein the probe, the fuse housing, the switch, and the lead connector are electrically connected in series such that an electrically-contiguous connection between the probe and the lead connector is only made when a fuse is in the fuse housing and the trigger is depressed.

12. A safety test jumper as recited in claim 11, further comprising a test lead connected to the lead connector.

13. A safety test jumper as recited in claim 11, further comprising a fuse connected to the fuse housing, the fuse being sized to prevent currents higher than a rated current of the device being tested from being delivered to the device being tested.

14. A safety test jumper as recited in claim 11, wherein the hand guard extends laterally to substantially cover the user's hand when the user's hand is gripping the hand grip.

15. A method for using a safety test jumper comprising:
providing a safety test jumper comprising:
a body comprising:
a hand grip having an upper end and a lower end;
an upper body portion housing a probe, the upper body portion having a rear portion attached at the upper end of the hand grip and a front portion; and
a hand guard extending between the lower end of the hand grip and the front portion of the upper body portion;
the probe comprising an electrical contacting portion at the front portion of the upper body portion;
a fuse housing incorporated into the body and configured to receive a fuse;
a trigger incorporated into the body at a location that it can be readily activated by a user's hand gripping the hand grip;
a switch within the body activated by the trigger; and
a test lead;
wherein the probe, the fuse housing, the switch, and the test lead are electrically connected in series, whereby an electrically-contiguous connection between the probe and the test lead is only made when a fuse is in the fuse housing and the trigger is depressed;
determining a current rating for a device to be tested;
ensuring that a fuse sized to prevent currents over the current rating from flowing through the tester is within the fuse housing;
locating the test lead at a power source terminal;
locating the probe at a desired test location;
pulling the trigger to close the switch while the test lead and the probe are located at the desired positions to permit verification of proper functioning of the device to be tested.

16. A method as recited in claim 15, further comprising selecting a fuse and placing the fuse in the fuse housing.

17. A method as recited in claim 15, further comprising:
releasing the trigger after verifying one of functioning and the lack thereof of the device to be tested at the test location; and
removing one or both of:
the test lead from the power source terminal; and
the probe from the desired test location.

18. A method as recited in claim 17, further comprising testing a second test location by repeating at least one of the steps of:
determining a current rating;
ensuring a properly-sized fuse is in the fuse housing;
locating the test lead at a power source terminal;
locating the probe at the second test location; and
pulling the trigger.

19. A method as recited in claim 15, further comprising using the hand guard to prevent contact between the user's hand and any unshielded components of the device being tested.

20. A method as recited in claim 15, further comprising connecting the test lead to the body.
